(19) United States
(12) Patent Application Publication
(10) Pub. No.: US 2024/0395802 A1
(43) Pub. Date: Nov. 28, 2024

(54) DIODE-CONTAINING COMPONENT AND METHOD FOR MANUFACTURING THE SAME

(71) Applicant: TAIWAN SEMICONDUCTOR MANUFACTURING COMPANY, LTD., Hsinchu (TW)

(72) Inventors: Dai-Yan WU, Hsinchu (TW); Yu-Chiun LIN, Hsinchu (TW); Po-Nien CHEN, Hsinchu (TW); Hsiao-Han LIU, Hsinchu (TW); Chih-Yung LIN, Hsinchu (TW)

(73) Assignee: TAIWAN SEMICONDUCTOR MANUFACTURING COMPANY, LTD., Hsinchu (TW)

(21) Appl. No.: 18/323,179

(22) Filed: May 24, 2023

(51) Int. Cl. H01L 27/06; H01L 21/8249; H01L 29/06; H01L 29/423; H01L 29/66; H01L 29/73; H01L 29/775

(52) U.S. Cl. CPC H01L 27/0623; H01L 21/8249; H01L 29/0673; H01L 29/42392; H01L 29/66265; H01L 29/66439; H01L 29/66545; H01L 29/7317; H01L 29/775

(57) ABSTRACT

A semiconductor structure includes a base structure, a first portion, a second portion and a first stack. The first portion and the second portion are disposed on the base structure and are respectively made of a first semiconductor material and a second semiconductor material which has a conductivity type opposite to that of the first semiconductor material. The first stack is disposed on the base structure and between the first portion and the second portion. The first stack includes a plurality of first semiconductor regions and a plurality of first dielectric regions disposed to alternate with the first semiconductor regions, such that each of the first semiconductor regions and the first dielectric regions extends between the first portion and the second portion. The first semiconductor regions has a dopant concentration which is lower than that of each of the first portion and the second portion.

### BACKGROUND

With rapid development of semiconductor technology, critical dimension (CD) of metal-oxide-semiconductor field-effect transistors (MOSFETs) keeps shrinking and various three-dimensional (3D) structures for MOSFETs are being developed, making it possible to integrate more MOSFETs per unit area. Additionally, diodes and other types of transistors are also being continuously developed to have different configurations so as to integrate a process flow for making the diodes and other types of transistors into a process flow for making MOSFETs in advanced technology nodes.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a schematic sectional view illustrating a semiconductor structure in accordance with some embodiments.

FIGS. 2 and 3 are schematic sectional views respectively taken along lines A-A′ and B-B′ of FIG. 1 in accordance with some embodiments.

FIG. 4 is a schematic sectional view illustrating another semiconductor structure in accordance with some embodiments.

FIG. 5 is a flow diagram illustrating a method for manufacturing a semiconductor structure in accordance with some embodiments.

FIGS. 6 to 17 illustrate schematic views of intermediate stages of the method depicted in FIG. 5 in accordance with some embodiments.

### DETAILED DESCRIPTION

The following disclosure provides many different embodiments, or examples, for implementing different features of the disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “on,” “above,” “top,” “bottom,” “upper,” “lower,” “over,” “beneath,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

For the purposes of this specification and appended claims, unless otherwise indicated, all numbers expressing amounts, sizes, dimensions, proportions, shapes, formulations, parameters, percentages, quantities, characteristics, and other numerical values used in the specification and claims, are to be understood as being modified in all instances by the term “about” even though the term “about” may not expressly appear with the value, amount or range. Accordingly, unless indicated to the contrary, the numerical parameters set forth in the following specification and attached claims are not and need not be exact, but may be approximate and/or larger or smaller as desired, reflecting tolerances, conversion factors, rounding off, measurement error and the like, and other factors known to those of skill in the art depending on the desired properties sought to be obtained by the presently disclosed subject matter. For example, the term “about,” when referring to a value can be meant to encompass variations of, in some aspects ±10%, in some aspects ±5%, in some aspects ±2.5%, in some aspects ±1%, in some aspects ±0.5%, and in some aspects ±0.1% from the specified amount, as such variations are appropriate to perform the disclosed methods or employ the disclosed compositions.

Diodes and bipolar junction transistors are usually formed by subjecting a p-type substrate to a plurality of implantation processes, such that a plurality of implant regions which have different depths, different conductivity types of dopants and different concentrations of the dopants are formed in the p-type substrate. For example, the diode may include a deep n-well region formed on the p-type substrate, a p-well region formed on the deep n-well region, a heavily-doped n-type region formed on the p-well region, and a heavily-doped p-type region formed on the p-well region and spaced apart from the heavily-doped n-type region by a shallow trench isolation. The heavily-doped n-type region and the heavily-doped p-type region respectively serve as a cathode and an anode of the diode, and the deep n-well region is used to reduce a leakage current flowing between the p-well region and the p-type substrate. However, with rapid development of semiconductor technology, in advanced technology nodes (for example, but not limited to, 2 nm technology or below), the substrate may be thinned down by removing a back portion of the substrate to form a backside surface opposite to a front-side surface on which electronic components are generally located. Afterwards, a backside metallization scheme may be further formed on the backside surface of the thinned down substrate to reduce routing congestion of a front-side metallization scheme which is formed over the front-side surface and which is connected to the electronic components. In this case, the deep n-well region of the diode for reducing current leakage may be removed or thinned with the removal of the back portion of the substrate. Therefore, the present disclosure is directed to a diode-containing component having a configuration which may be integrated to an advanced integrated circuit and which is not influenced by whether the advanced integrated circuit includes the backside metallization scheme or not. Furthermore, for the configuration of the diode-containing component of the present disclosure, loss of current flowing through the diode-containing component due to materials and/or fabrication processes is also reduced.

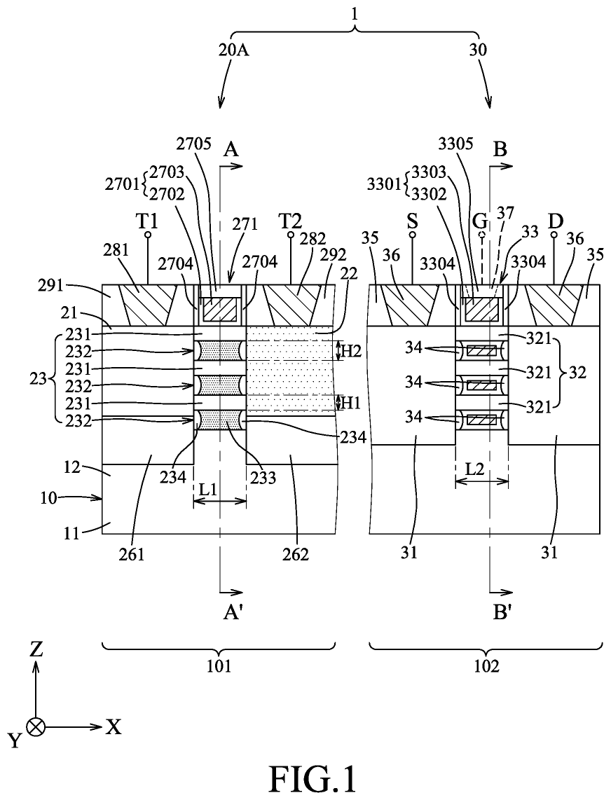

FIG. 1 is a schematic sectional view illustrating a semiconductor structure 1 in accordance with some embodiments. Some repeating structures are omitted in FIG. 1 and the following figures for the sake of brevity.

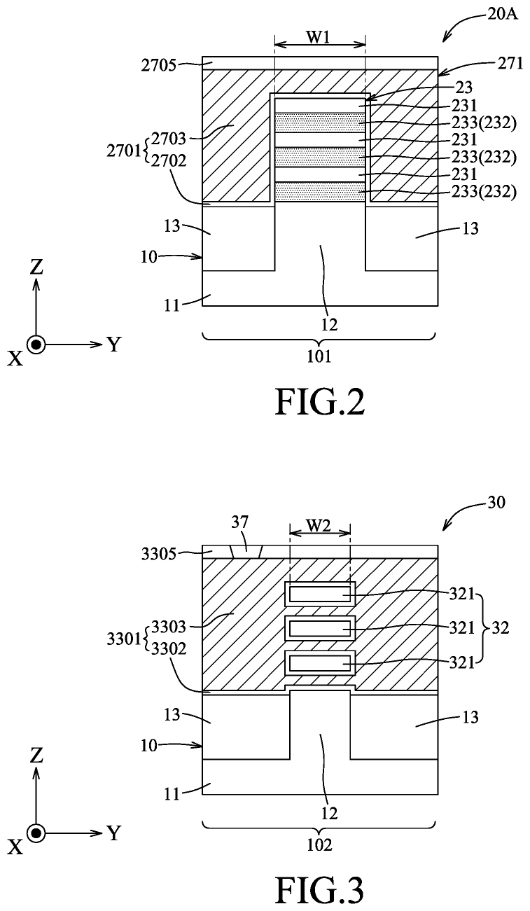

The semiconductor structure 1 includes a base structure 10 having a first part 101 and a second part 102 displaced from the first part 101, a diode-containing component 20A disposed on the first part 101, and an active component 30 disposed on the second part 102. FIGS. 2 and 3 are schematic sectional views respectively taken along line A-A′ and line B-B′ of FIG. 1 in accordance with some embodiments.

The diode-containing component 20A includes a first portion 21, a second portion 22 and a first stack 23 which are disposed on the first part 101. The first portion 21 and the second portion 22 are spaced apart from each other in an X direction, and the first stack 23 is disposed between the first portion 21 and the second portion 22.

The first portion 21 is made of a first semiconductor material, and the second portion 22 is made of a second semiconductor material which has a conductivity type opposite to that of the first semiconductor material. In some embodiments, the first semiconductor material may include single crystalline or polycrystalline silicon, single crystalline or polycrystalline silicon germanium, or other suitable materials doped with a p-type impurity to have a p-type conductivity. The p-type impurity may be, for example, but not limited to, boron (B), aluminum (Al), gallium (Ga), indium (In), other suitable materials, or combinations thereof. In some embodiments, the p-type impurity in the first semiconductor material may be in a dopant concentration ranging from about 1E19atoms/cm³ to about 1E21 atoms/cm³. The second semiconductor material may include single crystalline or polycrystalline silicon, single crystalline or polycrystalline silicon germanium, or other suitable materials doped with an n-type impurity to have an n-type conductivity. The n-type impurity may be, for example, but not limited to, nitrogen (N), phosphorous (P), arsenic (As), antimony (Sb), other suitable materials, or combinations thereof. In some embodiments, the n-type impurity in the second semiconductor material may be in a dopant concentration ranging from about 1E19 atoms/cm³ to about 1E21atoms/cm³. In some alternative embodiments, the first semiconductor material may be doped with the n-type impurity to have an n-type conductivity, and the second semiconductor material may be doped with the p-type impurity to have a p-type conductivity. In some embodiments, each of the first and second portions 21, 22 may be formed as a single layer structure or a multi-layered structure having several sub-layers with different dopant concentration.

The first stack 23 includes a plurality of first semiconductor regions 231 spaced apart from each other in a Z direction transverse to the X direction, and a plurality of first dielectric regions 232 disposed to alternate with the first semiconductor regions 231 such that each of the first semiconductor regions 231 and the first dielectric regions 232 extends between the first portion 21 and the second portion 22.

In some embodiments, each of a first number N1 of the first semiconductor regions 231 and a second number N2 of the first dielectric regions 232 is three, as shown in FIGS. 1 and 2, but is not limited thereto. The first number N1 may vary according to practical applications of the diode-containing component 20A, and the second number N2 may vary according to the first number N1. For example, in some not shown embodiments, the first number N1 may be designed to be three, and the second number N2 may be designed to be four. In some other not shown embodiments, each of the first number N1 and the second number N2 may be designed to be two, four or five. The first portion 21 is in contact with each of the first semiconductor regions 231 to form a plurality of first interfaces. The second portion 22 is in contact with each of the first semiconductor regions 231 to form a plurality of second interfaces. It is worth noting that a number of the first interfaces and a number of the second interfaces may increase as the first number N1 of the first semiconductor regions 231 increases, thereby adjusting the electrical performance (e.g., output current) of the diode-containing component 20A.

In some embodiments, each of the first semiconductor regions 231 may have a thickness H1 in the Z direction (see FIG. 1) ranging from about 3 nm to about 8 nm. In some embodiments, each of the first dielectric regions 232 may have a thickness H2 in the Z direction (see FIG. 1) ranging from about 5 nm to about 12 nm. In some embodiments, each of the first semiconductor regions 231 and the first dielectric regions 232 may have a length L1 in the X direction (see FIG. 1) ranging from about 100 nm to about 200 nm, as show in FIG. 1. In some embodiments, each of the first semiconductor regions 231 and the first dielectric regions 232 may have a width W1 in a Y direction transverse to both the X and Z directions (see FIG. 2) ranging from about 5 nm to about 80 nm, as show in FIG. 2. It is noted that the dimension of each of the first semiconductor regions 231 and the first dielectric regions 232 is not limited to the range as described above, and other value ranges are also within the scope of this disclosure. The dimension of each of the first semiconductor regions 231 and the first dielectric regions 232 may vary according to practical applications and/or process limitation of photolithography. In some embodiments, the X, Y and Z directions are perpendicular to each other.

In some embodiments, the first semiconductor regions 231 may be made of elemental semiconductor materials, such as crystalline silicon, diamond or germanium; compound semiconductor materials, such as silicon carbide, gallium arsenic, indium arsenide, or indium phosphide; or alloy semiconductor materials, such as silicon germanium, silicon germanium carbide, gallium arsenic phosphide, or gallium indium phosphide. Other semiconductor materials suitable for the first semiconductor regions 231 are within the contemplated scope of the present disclosure. In some embodiments, the semiconductor material of the first semiconductor regions 231 may be lightly doped with an n-type impurity or a p-type impurity (such as the examples described in the preceding paragraph), and has a dopant concentration which is lower than that of each of the first semiconductor material of the first portion 21 and the second semiconductor material of the second portion 22. In some alternative embodiments, the semiconductor material of the first semiconductor regions 231 is intrinsic or un-doped with an n-type impurity or a p-type impurity.

In some embodiments, each of the first dielectric regions 232 is disposed to fill a space between two corresponding adjacent ones of the first semiconductor regions 231. In some embodiments, each of the first dielectric regions 232 includes a main part 233 and two lateral parts 234 which are respectively disposed at two opposite sides of the main part 233 in the X direction, and which are connected to the first portion 21 and the second portion 22, respectively.

In some embodiments, the main part 233 may include dielectric material(s) to be formed as a single layer structure, a bi-layered structure or a multi-layered structure. In some embodiments, the dielectric material(s) of the main part 233 include an oxide, a nitride, a carbide, an oxynitride, an oxycarbide, a carbonitride, an oxycarbonitride, or combinations thereof. For example, the main part 233 may include silicon oxide, silicon nitride, silicon oxynitride, silicon carbon nitride, silicon oxycarbonitride, silicon oxycarbide, silicon carbide, aluminum oxide, aluminum nitride, titanium nitride, hafnium oxide, zirconium oxide, or combinations thereof, but is note limited thereto. In certain embodiments, the main part 233 may include silicon oxide, metal oxide (for example, but not limited to, aluminum oxide, hafnium oxide, zirconium oxide, or combinations thereof), or a combination thereof. Other dielectric materials and configurations suitable for the main part 233 are within the contemplated scope of the present disclosure. In some embodiments, to ensure less defects at an interface of one of the first semiconductor regions 231 and an adjacent one of the first dielectric regions 232, nitride materials are excluded from materials of the first dielectric regions 232 (in particular, nitride materials are excluded from materials of the main part 233).

In some embodiments, possible dielectric materials suitable for the two lateral parts 234 are similar to those for the main part 233, and the details thereof are omitted for the sake of brevity. In certain embodiments, the two lateral parts 234 may include a low-k dielectric material, such as silicon oxide, silicon nitride, silicon oxynitride, silicon carbonitride, silicon oxycarbide, silicon oxycarbonitride, silicon carbide, and so on. Other dielectric materials suitable for the two lateral parts 234 are within the contemplated scope of the present disclosure. In some embodiments, the dielectric materials of the main part 233 and the two lateral parts 234 may be the same as or different from each other.

In some embodiments, the diode-containing component 20A further includes two isolation portions 261. 262, each of which is disposed between the base structure 10 and a corresponding one of the first portion 21 and the second portion 22, and each of which is configured to entirely separate the corresponding one of the first portion 21 and the second portion 22 from the base structure 10. The bottommost one of the first semiconductor regions 231 has two end surfaces which are opposite to each other in the X direction and which are respectively in contact with the first portion 21 and the second portion 22. Each of the isolation portions 261, 262 has an upper surface having a level which is lower than a level of a lower surface of a bottommost one of the first semiconductor regions 231, and which is higher than a level of a lower surface of a bottommost one of the first dielectric regions 232. As such, the two end surfaces of the bottommost one of the first semiconductor regions 231 will not be covered by the isolation portions 261, 262, respectively.

In some embodiments, each of the isolation portions 261, 262 may include dielectric material(s) and may be formed as a single layer structure, a bi-layered structure or a multi-layered structure. In some embodiments, possible dielectric materials suitable for the isolation portions 261, 262 are similar to those for the main part 233, and thus the details thereof are omitted for the sake of brevity. Other dielectric materials suitable for the isolation portions 261, 262 are within the contemplated scope of the present disclosure.

In some embodiments, as shown in FIGS. 1 and 2, the diode-containing component 20A further includes (i) a first dummy gate structure 271 which is elongated in the Y direction and which is disposed over the first stack 23, (ii) two inter-layer dielectric portions 291, 292 which are respectively disposed to cover the first portion 21 and the second portion 22, and (iii) two contact portions 281, 282 which are respectively formed in the two inter-layer dielectric portions 291, 292 to be connected to the first portion 21 and the second portion 22, respectively. In some embodiments, the first dummy gate structure 271 includes (i) a gate portion 2701 which includes a gate dielectric 2702 and a gate electrode 2703 sequentially disposed over the first stack 23 (see FIG. 2), (ii) two wall portions 2704 which are respectively disposed at two opposite sides of the gate portion 2701 in the X direction (see FIG. 1), and which may be referred to as gate spacers, and (iii) a cap portion 2705 disposed to cover the gate portion 2701. In some embodiments, the two wall portions 2704 are disposed on the first stack 23, and spaced apart from each other in the X direction, as shown in FIG. 1. In some embodiments, the cap portion 2705 has an upper surface which is flush with an upper surface of each of the wall portions 2704, as shown in FIG. 1. It is noted that each of the two contact portions 281, 282 is connected to an external circuit or an external controller through a front-side backend metallization scheme (not shown) disposed over the semiconductor structure 1, such that a voltage can be applied across the first portion 21 and the second portion 22 through the two contact portions 281, 282. On the contrary, the first dummy gate structure 271 is formed during formation of the semiconductor structure 1 to obtain a relatively uniform pattern density in a patterning process, and thus no voltage is applied to the first dummy gate structure 271 by an external circuit or an external controller through the front-side backend metallization scheme. Materials of the first dummy gate structure 271 may vary according to those of the active component 30, and thus will be described in the following description of the active component 30.

In some embodiments, each of the inter-layer dielectric portions 291, 292 may may be formed as a single layer structure or a multi-layered structure, and include a dielectric material, such as silicon oxide, silicon nitride, silicon oxynitride, other suitable low-k dielectric materials, or combinations thereof. Other dielectric materials suitable for the inter-layer dielectric portions 291, 292 are within the contemplated scope of the present disclosure.

In some embodiments, each of the contact portions 281, 282 may include a conductive material, such as tungsten (W), aluminum (Al), ruthenium (Ru), cobalt (Co), copper (Cu), palladium (Pd), nickel (Ni), platinum (Pt), a low resistivity metal constituent, or the like, or combinations thereof. Other conductive materials suitable for the contact portions 281, 282 are within the contemplated scope of the present disclosure.

In some embodiments, the diode-containing component 20A shown in FIG. 1 functions as a diode, which is a two-terminal electronic component. In FIG. 1, the two symbols “T1” and “T2” represent the two terminals of the diode, and correspond to the first portion 21 and the second portion 22, respectively. Since one of the first portion 21 and the second portion 22 has a p-type conductivity which serves as a p-type region or an anode of the diode, since the other one of the first portion 21 and the second portion 22 has an n-type conductivity which serves as an n-type region or a cathode of the diode, and since the first semiconductor regions 231 extending between the first portion 21 and the second portion 22 have a dopant concentration lower than that of each of the first and second portions 21, 22 and serve as an intrinsic region, the diode may be referred to as a

PIN diode which has a p-type/intrinsic/n-type structure. Each of the anode and the cathode is connected to an external circuit through a corresponding one of the contact portions 281, 282. When a forward bias voltage is applied across the anode and the cathode of the diode, electrons are permitted to flow from the cathode to the anode through the first semiconductor regions 231 of the first stack 23. The diode shown in FIG. 1 has advantages as described hereininafter. Since less defects (for example, but not limited to, dislocations due to lattice mismatch) may be formed at the interface of one of the first semiconductor regions 231 and an adjacent one of the first dielectric regions 232. carriers (e.g., electrons) travelling in the first semiconductor regions 231 may be less likely to be trapped by the defects, thereby enlarging lifetime of the carriers and obtaining a higher forward current output from the cathode. Furthermore, the isolation portions 261, 262, each of which is disposed to isolate a corresponding one of the first portion 21 and the second portion 22 from the base structure 10, may reduce leakage current flowing from any one of the first portion 21 and the second portion 22 to a backside metallization scheme (not shown) which is formed on the base structure 10 opposite to the diode (i.e., the diode-containing component 20A). Additionally, the first number N1 of the first semiconductor regions 231 may be increased to enlarge the number of the first interfaces and the number of the second interfaces, thereby allowing a relatively higher forward current to be output from the cathode when a forward bias is applied to the PIN diode.

In some embodiments, the active component 30 may include a metal-oxide-semiconductor field-effect transistor (MOSFET). In some embodiments, the active component 30 may be configured as a fin-type FETs (FinFET), multi-gate FETs (e.g., gate-all-around FETs (GAA FETs), multi-bridge channel FETs (MBCFET), fork-sheet FETs, etc.), or other FETs having a suitable structure. In some embodiments, the active component 30 may be configured as a memory cell or an inverter both of which may include a plurality of transistors. Other applications or devices suitable for the active component 30 are within the contemplated scope of the present disclosure. In some embodiments, the active component 30 is functions as a MOSFET, and includes (i) two source/drain portions 31 disposed on the second part 102 of the base structure 10 and spaced apart from each other in the X direction (see FIG. 1), (ii) a channel portion 32 disposed to extend between the two source/drain portions 31 (see FIG. 1), and (iii) an active gate structure 33 elongated in the Y direction and disposed over the channel portion 32 (see FIG. 3).

In some embodiments, the two source/drain portions 31 are made of the same semiconductor material and have the same conductivity type. Furthermore, the conductivity type of the two source/drain portions 31 is the same as that of one of the first portion 21 and the second portion 22. Possible semiconductor materials suitable for the two source/drain portions 31 are similar to those for the first portion 21 and the second portion 22, and thus the details thereof are omitted for the sake of brevity. It is noted that each of the two source/drain portions 31 may refer to a source or a drain, individually or collectively dependent upon the context.

In some embodiments, in the case that the active component 30 is configured to have a gate-all-around structure, as shown in FIGS. 1 and 3, the channel portion 32 may include a plurality of channel regions 321 stacked on and spaced apart from each other in the Z direction. Each of the channel regions 321 is made of a semiconductor material the same as that of the first semiconductor regions 231. Possible semiconductor materials suitable for the channel regions 321 are similar to those for the first semiconductor regions 231, and thus the details thereof are omitted for the sake of brevity. In some embodiments, each of the channel regions 321 may have a length L2 in the X direction ranging from about about 15 nm to about 50 nm. In some embodiments, each of the channel regions 321 may have a width W2 in the Y direction ranging from about about 5 nm to about 80 nm. In some embodiments, each of the channel regions 321 may have a thickness the same as that of each of the first semiconductor regions 231. In some embodiments, a number of the channel regions 321 may be the same as the first number N1 of the first semiconductor regions 231, as shown in FIG. 1. In some not shown embodiments, the number of the channel regions 321 may be different from the first number N1 of the first semiconductor regions 231.

In some embodiments, as shown in FIGS. 1 and 3, the active gate structure 33 includes (i) a gate portion 3301 which includes a gate dielectric 3302 and a gate electrode 3303 sequentially disposed to surround the channel regions 321 (see FIG. 3) such that each of the channel regions 321 of the channel portion 32 is isolated from the gate electrode 3303 by the gate dielectric 3302, (ii) two wall portions 3304 respectively disposed at two opposite sides of the gate portion 3301 in the X direction (see FIG. 1), and (iii) a cap portion 3305 disposed to cover the gate portion 3301. The gate electrode 3303 is used to control an electrical conductivity of the channel portion 32, that is, to control the channel portion 32 to be in an on-state or an off-state.

In some embodiments, the active gate structure 33 and the first dummy gate structure 271 are made of the same materials. To be specific, the materials of the gate dielectric 3302, the gate electrode 3303, the wall portion 3304, and the cap portion 3305 in the active gate structure 33 are the same as those of the gate dielectric 2702, the gate electrode 2703, the wall portion 2704, and the cap portion 2705 in the first dummy gate structure 271, respectively.

In some embodiments, the gate dielectric 3302 may include silicon oxide, silicon nitride, silicon oxynitride, a suitable high-k material (such as hafnium oxide, zirconium oxide, zirconium aluminum oxide, hafnium aluminum oxide, hafnium silicon oxide, aluminum oxide, and so on), other suitable materials, or combinations thereof. Other dielectric materials suitable for the gate dielectric 3302 are within the contemplated scope of the present disclosure.

In some embodiments, the gate electrode 3303 may be configured as a multi-layered structure including (i) at least one work function metal which is provided for adjusting threshold voltage of an n-FET or a p-FET, and (ii) an electrically conductive material having a low resistance which is provided for reducing electrical resistance of the gate electrode 3303, other suitable materials, or combinations thereof. In some embodiments, the work function metal of the gate electrode 3303 for forming an n-FET may be different from that for forming a p-FET so as to permit the n-FET and the p-FET to have different threshold voltages. Other methods suitable for adjusting the threshold voltages are within the contemplated scope of the present disclosure. In some embodiments, the gate electrode 3303 may include a metal material (e.g., tungsten (W), titanium (Ti), tantalum (Ta), aluminum (Al), or ruthenium (Ru)), metal-containing nitrides (e.g., titanium nitride (TiN), or tantalum nitride (TaN)), metal-containing silicides (e.g., nickel silicide (NiSi)), metal-containing carbides (e.g., tantalum carbide (TaC)), or combinations thereof. Other suitable materials for the gate electrode 3303 are within the contemplated scope of the present disclosure.

In some embodiments, the wall portions 3304 may be formed as a single layer structure or a multi-layered structure, and include a dielectric material. In some embodiments, the wall portions 3304 may include a nitride-based dielectric material, such as silicon nitride, silicon oxynitride, silicon carbon nitride, silicon oxycarbonnitride, but is not limited thereto. Other dielectric materials suitable for the wall portions 3304 are within the contemplated scope of the present disclosure.

In some embodiments, the cap portion 3305 has an upper surface which is flush with an upper surface of each of the wall portions 3304. In some embodiments, the cap portion 3305 may include a dielectric material, such as silicon oxide, silicon nitride, silicon oxynitride, but is not limited thereto. Other dielectric materials suitable for the cap portion 3305 are within the contemplated scope of the present disclosure.

Possible materials suitable for the elements 2702, 2703, 2704, 2705 in the first dummy gate structure 271 are similar to those for the elements 3302, 3303, 3304, 3305 in the active gate structure 33, and thus the details thereof are omitted for the sake of brevity.

In some embodiments, the active component 30 further includes a plurality pair of inner spacers 34, each pair of which are respectively disposed at two opposite sides of the gate portion 3301 in the X direction and disposed between two corresponding adjacent ones of the channel regions 321 so as to separate the gate portion 3301 from the two source/drain portions 31. In some embodiments, the inner spacers 34 may be made of a dielectric material the same as that of the lateral parts 234. Possible dielectric materials suitable for the inner spacers 34 are similar to those for the lateral parts 234, and thus the details thereof are omitted for the sake of brevity.

In some embodiments, the active component 30 further includes (i) two inter-layer dielectric portions 35 which are respectively disposed to cover the two source/drain portions 34, (ii) two contact portions 36 which are respectively formed in the two inter-layer dielectric portions 35 to be connected to the two source/drain portions 31, respectively, and (iii) a gate via 37 formed in the cap portion 3304 to be connected to the gate electrode 3303. In FIG. 1, the symbols “G,” “S,” and “D” respectively represent three terminals of the active component 30, and correspond to the gate electrode 3303, one of the two source/drain portions 34, and the other one of the source/drain portions 34, respectively. As such, operation of the active component 30 may be controlled by the two contact portions 36 and the gate via 37, each of which is connected to an external circuit or an external controller through the front-side backend metallization scheme (not shown) disposed over the semiconductor structure 1.

In some embodiments, the two inter-layer dielectric portions 35 and the two contact portions 36 may be made of materials respectively the same as those of the inter-layer dielectric portions 291, 292 and the contact portions 281, 282 in the diode-containing component 20A. Possible materials suitable for the two inter-layer dielectric portions 35 and the two contact portions 36 are respectively similar to those for the inter-layer dielectric portions 291, 292 and the contact portions 281, 282 in the diode-containing component 20A, and thus the details thereof are omitted for the sake of brevity. In some embodiments, the gate via 37 may be made of a conductive material, such as those of the contact portions 281, 282, and thus possible conductive materials suitable for the gate via 37 are not repeated for the sake of brevity.

In some embodiments, the base structure 10 includes a substrate 11, a plurality of fin portions 12 (see FIGS. 1 to 3), and a plurality of isolation regions 13. Each of the fin portions 12 may be elongated in the X direction and disposed on a front-side surface of the substrate 11. Furthermore, the fin portions 12 are spaced apart from each other in the Y directions by the isolation regions 13. As shown in FIGS. 2 and 3, at two opposite sides of each of the fin portions 12 in the Y direction, two corresponding ones of the isolation regions 13 are formed on the front-side surface of the substrate 11.

In some embodiments, the substrate 11 may include a semiconductor material (such as the examples for the first semiconductor regions 231 as described above with reference to FIG. 1). In some other embodiments, the substrate 11 may be a bulk silicon substrate, a silicon-on-insulator (SOI) substrate, or a germanium-on-insulator (GOI) substrate. Other suitable materials for the substrate 11 are within the contemplated scope of the present disclosure.

In some embodiments, the diode-containing component 20A and the active component 30 are disposed on the same one of the fin portions 12 and displaced from each other in the X direction. In this case, the fin portion 12 may have a first part 101 and a second part 102 which are in position, respectively corresponding to the first part 101 and the second part 102 of the base structure 10, and which are thus respectively denoted by the same numerals for the sake of brevity. In other words, the diode-containing component 20A and the active component 30 are respectively disposed on the first and second parts 101, 102 of the fin portion 12. In some embodiments, a width of the first part 101 of the fin portion 12 in the Y direction and a width of the second part 102 of the fin portion 12 are respectively equal to the width W1 of the first semiconductor regions 231 and the width W2 of the channel regions 321. In some embodiments, the width of the first part 101 of the fin portion 12 may be the same as or different from the width of the second part 102 of the fin portion 12. In some other embodiments, the diode-containing component 20A and the active component 30 are disposed on two different ones of the fin portions 12 and may be displaced from each other in the Y direction. In some not shown embodiments, the substrate includes a backside portion opposite to the front-side surface, and the backside portion of the substrate may be thinned down to have a backside surface. The semiconductor structure 1 may further include a backside metallization scheme (not shown) which is formed on the backside surface of the thinned-down substrate, and which is used to control electronic components disposed on the front-side surface.

In some embodiments, each of the isolation regions 13 are provided for isolating a corresponding one of the fin portions 12 from the structure adjacent thereto. The isolation regions 13 may each be a portion of a shallow trench isolation (STI), a deep trench isolation (DTI), or other suitable structures, and may be made of a dielectric material, such as an oxide material (for example, silicon oxide), a nitride material (for example, silicon nitride), or a combination thereof. Other suitable materials and/or configurations for the isolation regions 13 are within the contemplated scope of the present disclosure.

In some alternative embodiments, the semiconductor structure 1 may further include additional features, and/or some features present in the semiconductor structure 1 may be modified, replaced, or eliminated without departure from the spirit and scope of the present disclosure.

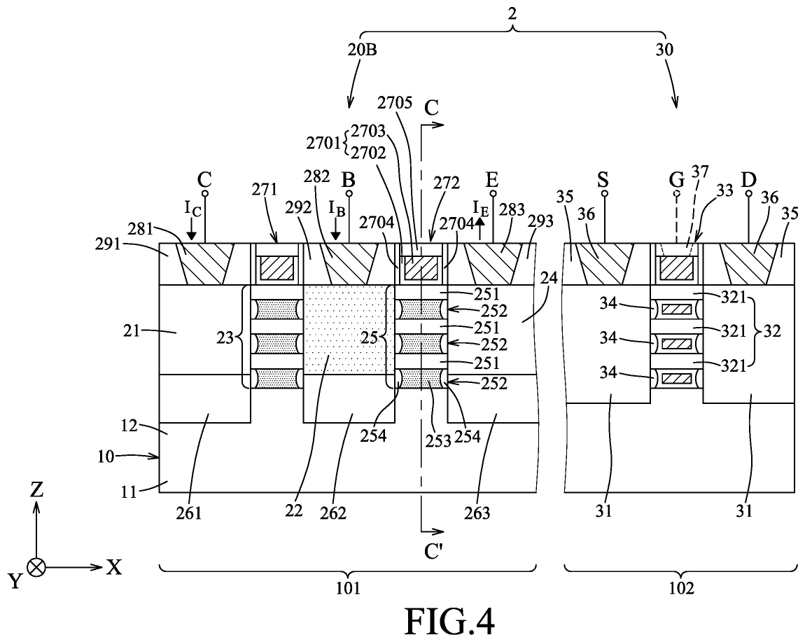

FIG. 4 is a schematic sectional view illustrating another semiconductor structure 2 in accordance with some embodiments. The semiconductor structure 2 has a structure similar to that of the semiconductor structure 1, but is difference in configuration of the diode-containing component. Therefore, the diode-containing component in the semiconductor structure 2 is denoted by 20B.

In some embodiments, the diode-containing component 20B has a structure similar to that of the diode-containing component 20A shown in FIG. 1, but the diode-containing component 20B further includes a third portion 24, a second stack 25, a second dummy gate structure 272, an additional isolation portion 263, an additional inter-layer dielectric portion 293, and an additional contact portions 283. The schematic sectional view taken along line C-C′ of FIG. 4 has a structure similar to that shown in FIG. 2, and thus is omitted for the sake of brevity.

The third portion 24 is disposed on the first part 101 such that the second portion 22 is disposed between and spaced apart from the first portion 21 and the third portion 24 in the X direction. The third portion 24 is made of a third semiconductor material which has a conductivity type the same as that of the first semiconductor material of the first portion 21. Possible materials suitable for the third semiconductor material are similar to those for the first portion 21, and thus the details thereof are omitted for the sake of brevity.

The second stack 25 is disposed on the first part 101 and between the second portion 22 and the third portion 24. The second stack 25 includes a plurality of second semiconductor regions 251 spaced apart from each other in the Z direction, and a plurality of second dielectric regions 252 disposed to alternate with the second semiconductor regions 251 such that each of the second semiconductor regions 251 and the second dielectric regions 252 extends between the second portion 22 and the third portion 24. Possible materials suitable for the second semiconductor regions 251 and the second dielectric regions 252 are respectively similar to those for the first semiconductor regions 231 and the first dielectric regions 232 as described above with reference to FIG. 1, and thus the details thereof are omitted for the sake of brevity. The second semiconductor regions 251 have a dopant concentration which is lower than that of each of the second portion 22 and the third portion 24. For example, in some embodiments, the semiconductor material of the second semiconductor regions 251 may be doped with an n-type impurity or a p-type impurity (such as the examples described in the preceding paragraph), and has a dopant concentration which is lower than that of each of the second semiconductor material of the second portion 22 and the third semiconductor material of the third portion 24. In some alternative embodiments, the semiconductor material of the second semiconductor regions 251 is intrinsic or undoped with an n-type impurity or a p-type impurity.

In some embodiments, each of the second dielectric regions 252 is disposed to fill a space between two corresponding adjacent ones of the second semiconductor regions 251. In some embodiments, each of the second dielectric regions 252 may have a configuration the same as that of each of the first dielectric regions 232, and includes a main part 253 and two lateral parts 254 which are respectively disposed at two opposite sides of the main part 253 in the X direction. In some embodiments, the main part 253 of each of the second dielectric regions 252 may be made of a dielectric material the same as the main part 233 of each of the first dielectric regions 232 as described above with reference to FIG. 1. The lateral part 254 of each of the second dielectric regions 252 may be made of a dielectric material the same as the lateral part 234 of each of the first dielectric regions 232 as described above with reference to FIG. 1.

In some embodiments, the additional isolation portion 263 is disposed between the base structure 10 and the third portion 24 to entirely separate the third portion 24 from the base structure 10 (i.e., the first part 101). Each of the isolation portions 262, 263 has an upper surface having a level which is lower than a level of a lower surface of a bottommost one of the second semiconductor regions 251, and which is higher than a level of a lower surface of a bottommost one of the second dielectric regions 252. As such, the bottommost one of the second semiconductor regions 251 has two end surfaces which are opposite to each other in the X direction and which are respectively in contact with the second portion 22 and the third portion 24, and the two end surfaces of the bottommost one of the second semiconductor regions 251 will not be covered by the isolation portions 262, 263, respectively. Possible dielectric materials suitable for the additional isolation portion 263 are similar to those for the isolation portions 261, 262, and the details thereof are not repeated for the sake of brevity. In some embodiments, the isolations portions 261, 262 may be each referred to as a full bottom isolation (FBI).

The second dummy gate structure 272 is elongated in the Y direction and disposed over the second stack 25. Elements of the second dummy gate structure 272 are similar to or the same as those of the first dummy gate structure 271 in terms of configurations and materials, and are denoted by the same numerals. As such, the details of the elements of the second dummy gate structure 272 are not repeated for the sake of brevity.

The additional inter-layer dielectric portion 293 is disposed to cover the third portion 24, and the dielectric materials and configuration of the additional inter-layer dielectric portion 293 are similar to those of the inter-layer dielectric portions 291, 292. and thus the details thereof are not repeated for the sake of brevity.

The additional contact portion 283 is formed in the additional inter-layer dielectric portion 293 and connected to the third portion 24. The additional contact portion 283 may include a conductive material, such as those of the contact portions 281, 282, and thus possible conductive materials for the additional contact portion 283 are not repeated for the sake of brevity.

It is noted that the additional contact portion 283 is connected to an external circuit or an external controller through a front-side backend metallization scheme (not shown) disposed over the semiconductor structure 2, and that the second dummy gate structure 272 is formed during formation of the semiconductor structure 2 to obtain a relatively uniform pattern density in a patterning process, and thus no voltage is applied to the second dummy gate structure 272 by an external circuit or an external controller through the front-side backend metallization scheme.

In some embodiments, as shown in FIG. 4, the diode-containing component 20B functions as a bipolar junction transistor (BJT), which is a three-terminal electronic component. In FIG. 4, the three symbols “C,” “B,” and “E” represent the three terminals of the BJT, and corresponds to the first portion 21, the second portion 22, and the third portion 24, respectively. To be specific, the first portion 21, the second portion 22 and the third portion 24 respectively serve as a collector terminal, a base terminal and an emitter terminal of the BJT. In some embodiments, the diode-containing component 20B functions as a PNP type BJT, where the first portion 21 and the third portion 24 both have a p-type conductivity and the second portion 22 has an n-type conductivity. In some alternative embodiments, the diode-containing component 20B functions as an NPN type BJT, where the first portion 21 and the third portion 24 both have an n-type conductivity and the second portion 22 has a p-type conductivity.

As shown in FIG. 4, in the case that the diode-containing component 20B functions as an NPN type BJT, the three arrows indicate directions of three current flows I_{C}, I_{B}, I_{E} at the three terminals “C,” “B,” and “E,” respectively. Furthermore, when the BJT 20B is configured as a common-emitter BJT, where the base terminal serves as an input, the collector terminal serves as an output, and the emitter terminal is connected to a ground reference, and when a forward bias voltage is applied across the base terminal and the emitter terminal (i.e., a potential at the base terminal is higher or more positive than that at the emitter terminal) and a reverse bias voltage is applied across the base terminal and the collector terminal (i.e., a potential at the base terminal is lower than that at the collector terminal), the current I_{B} and the current I_{C} may be referred to as an input current and an output current. A ratio of the output current I_{C} to the input current I_{B} (i.e., I_{C}/I_{B}, which is referred to as a common-emitter current gain, represented by βF) is an index used to describe an efficiency of the BJT.

The BJT 20B shown in FIG. 4 has advantages as described hereinafter. Since less defects (for example, but not limited to, dislocations due to lattice mismatch) may be formed between the interface of one of the first semiconductor regions 231 and an adjacent one of the first dielectric regions 232 and/or an interface of one of the second semiconductor regions 251 and an adjacent one of the second dielectric regions 252. carriers (e.g., electrons) travelling in the first semiconductor regions 231 and the second semiconductor regions 251 may be less likely to be trapped by the defects, thereby enlarging lifetime of the carriers and obtaining a higher value of a ratio of the output current I_{C} to the input current IB. Furthermore, the isolation portions 261, 262, 263, each of which is disposed to isolate a corresponding one of the first portion 21, the second portion 22 and the third portion 24 from the base structure 10, are provided to reduce leakage current flowing between the first portion 21 and the third portion 24. Additionally, a number of the second semiconductor regions 251 may be increased to enlarge a number of third interfaces of the second portion 22 and each of the second semiconductor regions 251 and a number of fourth interfaces of the third portion 24 and each of the second semiconductor regions 251, thereby allowing the output current I_{C} to have a relatively higher value at the emitter terminal.

In some alternative embodiments, the semiconductor structure 2 may further include additional features, and/or some features present in the semiconductor structure 2 may be modified, replaced, or eliminated without departure from the spirit and scope of the present disclosure.

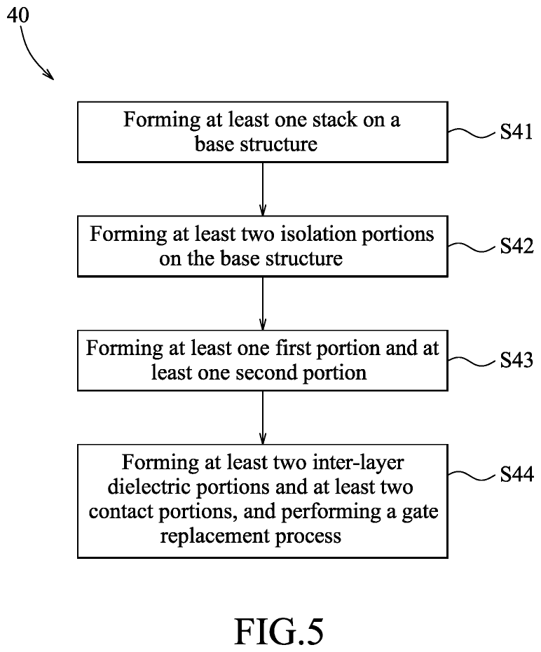

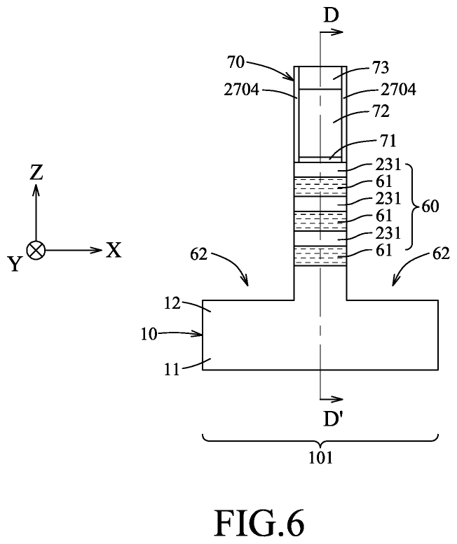

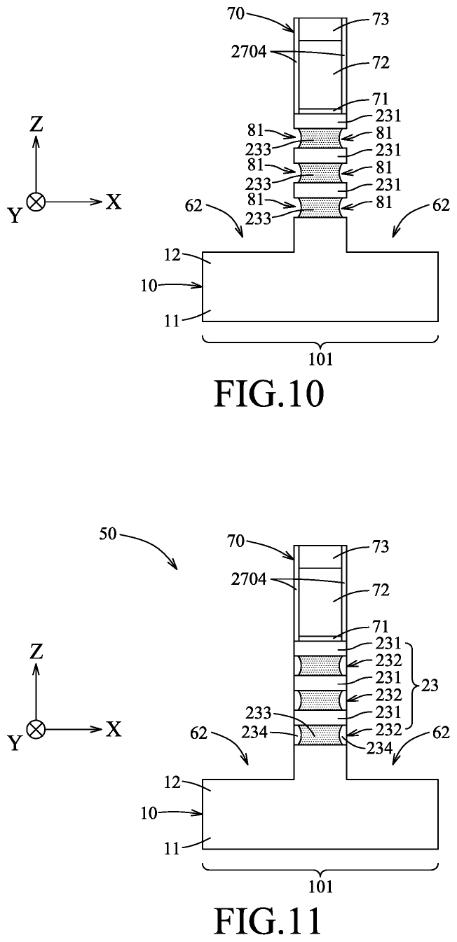

FIG. 5 is a flow diagram illustrating a method 40 for manufacturing a semiconductor structure in accordance with some embodiments. FIGS. 6 to 15 illustrate schematic views of intermediate stages of the method 40 for manufacturing, for example, but not limited to, the diode-containing component 20A in the semiconductor structure 1 shown in FIG. 1 in accordance with some embodiments. It is noted that similar numerals from the above-mentioned embodiments are used where appropriate, with some construction differences being indicated with different numerals.

In some embodiments, the method 40 may include steps S41 to S43.

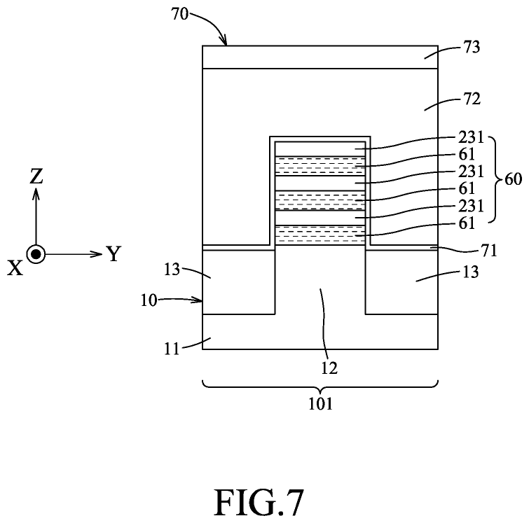

Referring to FIG. 5, the method 4 begins at step S41, where at least one stack which includes a plurality of semiconductor regions and a plurality of dielectric regions is formed on a base structure. Referring to the example illustrated in FIG. 11, a patterned structure 50 is formed. The patterned structure 50 includes the first stack 23 disposed on the first part 101 of the base structure 10, and a preformed gate structure 70 elongated in the Y direction and disposed over the first stack 23 (see FIG. 7). The details of the structures and materials of the base structure 10 and the first stack 23 are as described above with reference to FIG. 1, and not repeated for the sake of brevity.

In some embodiments, the preformed gate structure 70 includes the two wall portions 2704, a preformed gate dielectric layer 71, a preformed gate electrode layer 72 and a hard mask layer 73. The two wall portions 2704 are disposed on the first stack 23 and spaced apart from each other in the X direction. The preformed gate dielectric layer 71, the preformed gate electrode layer 72 and the hard mask layer 73 are sequentially formed over the first stack 23 in such order, and are each disposed between the two wall portions 2704. In some embodiments, the hard mask layer 73 may include silicon nitride, silicon oxide, silicon oxynitride, other suitable dielectric materials, or combinations thereof, the preformed gate electrode layer 72 may include polycrystalline silicon, single crystalline silicon, amorphous silicon, or combinations thereof, and the preformed gate dielectric layer 71 may include silicon oxide, silicon nitride, silicon oxynitride, high dielectric constant (k) materials, other suitable dielectric materials, or combinations thereof. Other suitable materials for the preformed gate structure 70 are within the contemplated scope of the present disclosure. The details of the structures and materials of the wall portions 2704 are already described above with reference to FIG. 1, and not repeated for the sake of brevity.

In some embodiments, step S41 may include sub-steps S411 to S413 in accordance with some embodiments.

In sub-step S411, referring to FIGS. 6 and 7, a preformed stack 60 is formed on the first part 101, and the preformed gate structure 70 is formed over the preformed stack 60. FIG. 7 is a schematic sectional view taken along line D-D′ of FIG. 6.

The preformed stack 60 includes the first semiconductor regions 231 and a plurality of preformed semiconductor regions 61 disposed to alternate with the first semiconductor regions 231 in the Z direction. Each of the preformed semiconductor regions 61 are made of a semiconductor material different from that of the first semiconductor regions 231. In other words, the semiconductor material of the preformed semiconductor regions 61 has a chemical composition different from that of the semiconductor material of the first semiconductor regions 231, such that the preformed semiconductor regions 61 and the first semiconductor regions 231 have different etching selectivity ratios from each other. Thus, by selecting a suitable etchant, the preformed semiconductor regions 61 or the first semiconductor regions 231 can be selectively removed in subsequent processes. Possible semiconductor materials suitable for the preformed semiconductor regions 61 are similar to those for the first semiconductor regions 231, and thus the details thereof are omitted for the sake of brevity. In some embodiments, the first semiconductor regions 231 are made of silicon, and the preformed semiconductor regions 61 are made of silicon germanium.

In some embodiments, the preformed gate structure 70 is not only formed over the preformed stack 60, but also further formed on the isolation regions 13.

In some embodiments, sub-step S411 may include: (i) forming a laminated structure (not shown) on the first part 101, the laminated structure including a plurality of first films and a plurality second films disposed to alternate with the first films in the Z direction; (ii) forming the preformed gate structure 70 over the laminated structure; and (iii) patterning the laminated structure using the preformed gate structure 70 as a hard mask to form two recesses 62 respectively at two opposite sides of the preformed gate structure 70 in the X direction, such that the first films are patterned into the first semiconductor regions 231 and the second films are patterned into the preformed semiconductor regions 61. One or more deposition processes (such as chemical vapor deposition (CVD), atomic layer deposition (ALD), physical vapor deposition (PVD), or other suitable deposition processes), one or more photolithography processes (such as coating a photoresist, exposing the photoresist through a photomask, developing the photoresist, etching through the developed photoresist, stripping or ashing the photoresist, and/or other suitable processes), one or more etching processes for patterning (such as dry etching, wet etching, other suitable techniques, or combinations thereof), and/or one or more planarization processes (such as chemical mechanical planarization (CMP), or other suitable planarization processes) may be used in sub-step S411, but is not limited thereto.

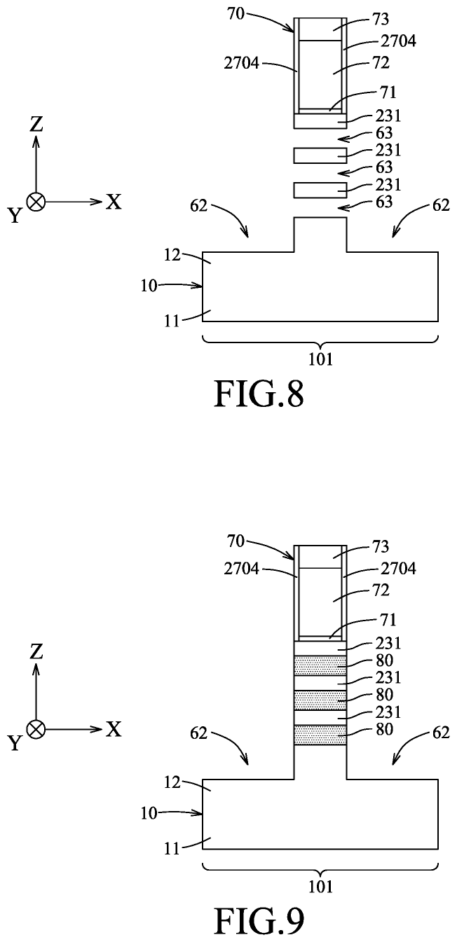

In sub-step S412, referring to FIG. 8, the preformed semiconductor regions 61 are removed to form a plurality of gaps 63, respectively, by a selective etching process with the use of etchant(s) having high etching selectivity to the preformed semiconductor regions 61 such that the first semiconductor regions 231 and the other elements 2704, 73, 12, 13 are substantially intact.

In sub-step S413, referring to FIG. 11, the first dielectric regions 232 are respectively formed to fill the gaps 63 such that preformed semiconductor regions 61 shown in FIGS. 6 and 7 are replaced with the first dielectric regions 232.

In some embodiments, referring to FIGS. 9 to 11, sub-step S413 may include (i) forming a plurality of first dielectric layers 80 to fill the gaps 63, respectively, (ii) recessing the first dielectric layers 80 such that the first dielectric layers 80 are each recessed to form two lateral grooves 81 through the two recesses 62, respectively, and such that each of the recessed first dielectric layers serves as the main part 233 of a corresponding one of the first dielectric regions 232, and (iii) forming the two lateral parts 234 of each of the first dielectric regions 232 respectively in the two lateral grooves 81 of a corresponding one of the recessed first dielectric layers 233. One or more deposition processes (such as CVD, ALD, PVD, or other suitable deposition processes), one or more patterned photoresist formation processes (such as coating a photoresist, exposing the photoresist through a photomask, developing the photoresist to form a patterned photoresist, and/or other suitable processes), one or more stripping or ashing processes for removal of the patterned photoresist, one or more etching processes for patterning (such as dry etching, wet etching, anisotropic etching, other suitable techniques, or combinations thereof), and/or other suitable processes may be used in sub-step S413, but is not limited thereto.

In some embodiments, in step S41, on the second part 102 (see also FIG. 1), a patterned structure (not shown), which has a configuration similar to that of the patterned structure 50, is formed together with the patterned structure 50 in a similar manner as described above. As such, after step S41, the not shown patterned structure on the second part 102 may include (i) the channel regions 321 (see FIG. 1), (ii) the inner spacers 34 (see FIG. 1), (iii) the wall portions 3304 (see FIG. 1), (iv) a dummy stack (not shown) similar to a stack including the elements 71, 72, 73 in terms of materials and configurations (see FIG. 9), and (v) dummy dielectrics (not shown) similar to the main parts 233 of the first dielectric regions 232 in terms of materials and configurations (see FIG. 11).

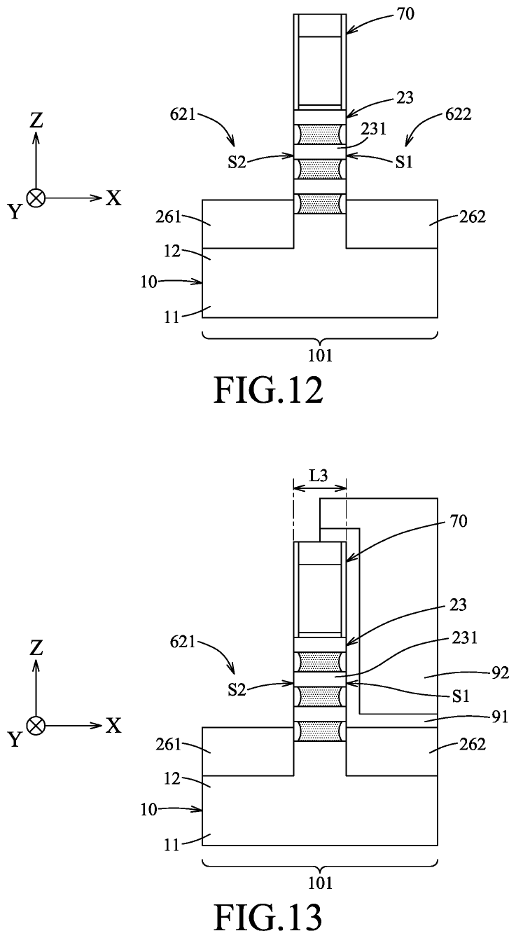

Referring to FIG. 5, the method 4 proceeds to step S42, where at least two isolation portions are formed on the base structure. Referring to the example illustrated in FIG. 12, the two isolation portions 261. 262 are formed on the first part 101 and respectively at two opposite sides of the first stack 23 in the X direction. It is noted that the two end surfaces of each of the first semiconductor regions 231 in the first stack 23 are not covered by the two isolation portions 261, 262. The details of the structures and materials of the isolations portions 261, 262 are as described above with reference to FIG. 1, and not repeated for the sake of brevity. In some embodiments, formation of the two isolation portions 261, 262 may include depositing a dielectric material layer for forming the isolation portions 261, 262 on the structure obtained after step S41 (e.g., the structure shown in FIG. 11) using a suitable deposition process (for example, but not limited to, CVD. ALD or other suitable techniques), followed by an etching back process (such as a dry etching, a wet etching, or a combination thereof), such that the dielectric material layer is formed into the two isolation portions 261, 262 respectively disposed on bottoms of the two recesses 62. After step S42, one of the remaining recesses positioned above the isolation portion 261 is denoted by 621, and the other one of the remaining recesses positioned above the isolation 262 is denoted by 622.

In some embodiments, in step S42, the not shown patterned structure formed on the second part 102 described in step S41 may be covered by a patterned photoresist (not shown), and the patterned photoresist may be removed after step S42. In some other embodiments, the not shown patterned structure formed on the second part 102 described in step S41 may be formed with two isolation regions similar to the isolation portions 261. 262 in terms of positions, configurations and materials.

Referring to FIG. 5, the method 4 proceeds to step S43, where at least one first portion and at least one second portion are respectively formed on the at least two isolation portions. Referring to the example illustrated in FIG. 15, the first portion 21 and the second portion 22 are respectively formed on the two isolation portions 261, 262 using an epitaxial growth process including CVD, molecular-beam epitaxy (MBE), an epitaxial deposition/partial etch process, such as a cyclic deposition-etch (CDE) process and/or a selective epitaxial growth (SEG) process, but is not limited thereto, such that each of the first semiconductor regions 231 and the first dielectric regions 232 in the first stack 23 extends between the first portion 21 and the second portion 22.

It is noted that since the conductivity types of the first portion 21 and the second portion 22 are different from each other, the first portion 21 and the second portion 22 are separately formed. The first portion 21 may be formed before or after formation of the second portion 22. In some embodiments, for example, referring to FIGS. 13 to 15, the first portion 21 is formed before forming the second portion 22.

In some embodiments, in step S43, the source/drain portions 31 shown in FIG. 1 have the same conductivity type as that of the first portion 21, and are formed together with the first portion 21. As such, the source/drain portions 31 have material(s) and configurations similar to those of the first portion 21. In some other embodiments, in step S43, the source/drain portions 31 shown in FIG. 1 have the same conductivity type as that of the second portion 22, and are formed together with the second portion 22. As such, the source/drain portions 31 have material(s) and configurations similar to those of the second portion 22. The source/drain portions 31 formed in step S43 are respectively formed at two opposite sides of the not shown patterned structure which is formed on the second part 102 and which is obtained in step S42.

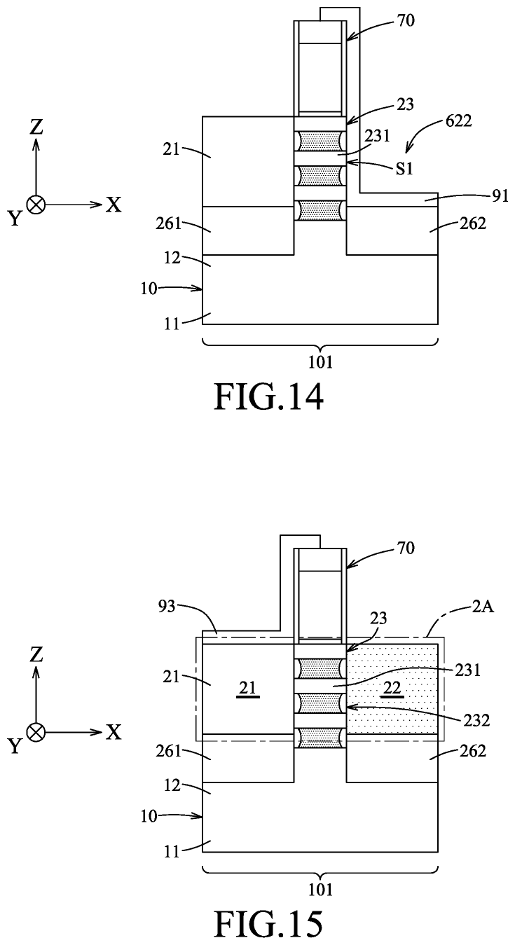

Referring to FIGS. 13 and 14, before the epitaxial growth of the first portion 21, a first patterned mask layer 91 is formed such that the isolation portion 262 and a first one S1 of the end surfaces of each of the first semiconductor regions 231 which is exposed from the recess 622 (see FIG. 12) are covered by the first patterned mask layer 91 and such that a second one S2 of the end surfaces of each of the first semiconductor regions 231 is exposed from the first patterned mask layer 91 through the recess 621. In some embodiments, formation of the first patterned mask layer 91 may include the following sub-steps of (i) depositing a first mask layer (not shown) using a suitable deposition process (CVD, ALD or other suitable techniques) on the structure shown in FIG. 12, (ii) forming a photoresist layer (not shown) on the first mask layer, (iii) performing an exposure and development process to pattern the photoresist layer so as to form a patterned photoresist layer 92, (iv) etching the first mask layer through the patterned photoresist layer 92 to obtain the first patterned mask layer 91, and (v) removing the patterned photoresist layer 92 from the first patterned mask layer 91 to prevent chamber contamination during the epitaxial growth of the first portion 21. Afterwards, referring to FIG. 14, the first portion 21 are epitaxially grown from the second one S2 of the end surfaces of each of the first semiconductor regions 231 to fill the recess 621 (see FIG. 13). After the epitaxial growth of the first portion 21, the first patterned mask layer 91 are removed from the structure shown in FIG. 14.

Referring to FIG. 15, before the epitaxial growth of the second portion 22, a second patterned mask layer 93 is formed in a manner similar to that for formation of the first patterned mask layer 91 such that the first portion 21 is covered by the second patterned mask layer 93 and such that the first one S1 of the end surfaces of each of the first semiconductor regions 231 is exposed from the second patterned mask layer 93 through the recess 622 (see also FIG. 14). Afterwards, the second portion 21 is epitaxially grown from the first one S1 of the end surfaces of each of the first semiconductor regions 231 to fill the recess 622. After the epitaxial growth of the second portion 22, the second patterned mask layer 93 will be removed from the structure shown in FIG. 15.

In some embodiments, each of the first patterned mask layer 91 and the second patterned mask layer 93 may include a dielectric material (such as silicon oxide, silicon nitride, silicon oxynitride, aluminum oxide, and so on). It is noted that a patterned photoresist layer (for example, but not limited to, the patterned photoresist layer 92) may have a dimension with an acceptable tolerance due to the process variation of the exposure and development process for forming the same, and hence, as shown in FIG. 13, the preformed gate structure 70 may have a length L3 in the X direction which is greater than the acceptable tolerance so as to ensure the first one S1 of the end surfaces of each of the first semiconductor regions 231 is covered by the first patterned mask layer 91. In some embodiments, the length L3 may range from about 100 nm to about 200 nm, and the length L1 of each of the first semiconductor regions 231 may be determined accordingly (see FIG. 1). With the progress of the exposure and development process, the length L3 can be smaller (e.g., less than about 100 nm), and the length L1 of the first semiconductor regions 231 can be also smaller, accordingly.

After step S43, the structure shown in area 2A of FIG. 15 may function as the PIN diode as described above with reference to FIG. 1.

In some embodiments, referring to FIG. 5, the method 40 may further includes step S44, where the two inter-layer dielectric portions 291, 292 shown in FIG. 1 are respectively formed to cover the first portion 21 and the second portion 22, the two contact portions 281, 282 shown in FIG. 1 are respectively formed in the two inter-layer dielectric portions 291, 292 to be respectively connected to the first portion 21 and the second portion 22. In addition, in step 44, a gate replacement process is performed to replace the preformed gate structure 70 with the first dummy gate structure 271, thereby obtaining the diode-containing component 20A shown in FIG. 1. In some embodiments, the gate replacement process and formation of the two inter-layer dielectric portions 291. 292 and the two contact portions 281, 282 may be performed using any suitable processes (e.g., one or more photolithography processes (such as coating a photoresist, exposing the photoresist through a photomask, developing the photoresist to obtain a patterned photoresist, etching through the patterned photoresist stripping or ashing the patterned photoresist, and/or other suitable processes), one or more etching processes for patterning, one or more ion implantation processes, one or more deposition processes (such as electroless plating, electroplating, PVD, CVD, ALD, or other suitable deposition processes), and/or one or more planarization processes (such as CMP, or other suitable planarization processes)), and thus details thereof are omitted for the sake of brevity.

In some embodiments, after step 44, the active component 30 may be also obtained on the second part 102 (see also FIG. 1). To be specific, (i) the inter-layer dielectric portions 35 are formed together with and in a manner similar to the inter-layer dielectric portions 292, (ii) the contact portions 36 are formed together with and in a manner similar to the contact portions 281, 282, (iii) in the gate replacement process, in addition to removal of the stack including elements 71, 72, 73 on the first part 101, the dummy stack (not shown) on the second part 102 (which is obtained in step S41) and the not shown dummy dielectrics (which is obtained in step S41) on the second part 102 are further selectively removed (meanwhile, the main parts 233 of the first dielectric regions 232 are protected by, for example, any suitable masks), and then the elements 2701, 2705 are formed together with the elements 3301 and 3305, and (iv) the gate via 37 is formed in the cap portion 3305 in a manner similar to the contact portions 36. As such, the processes for making the diode-containing component 20A can be integrated with the processes for making the active component 30.

In some embodiments, some steps in the method 40 may be modified, replaced, or eliminated without departure from the spirit and scope of the present disclosure.

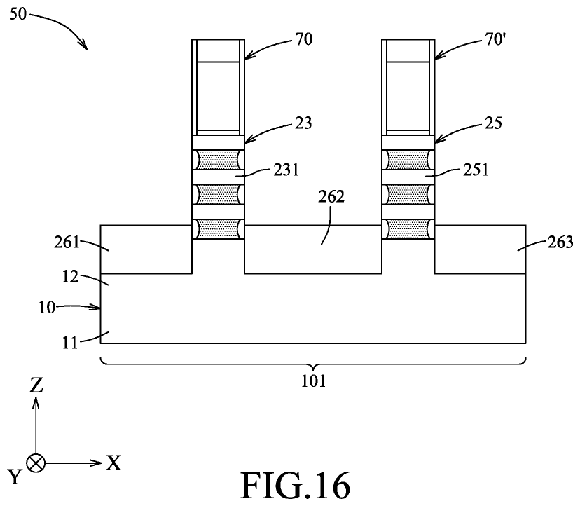

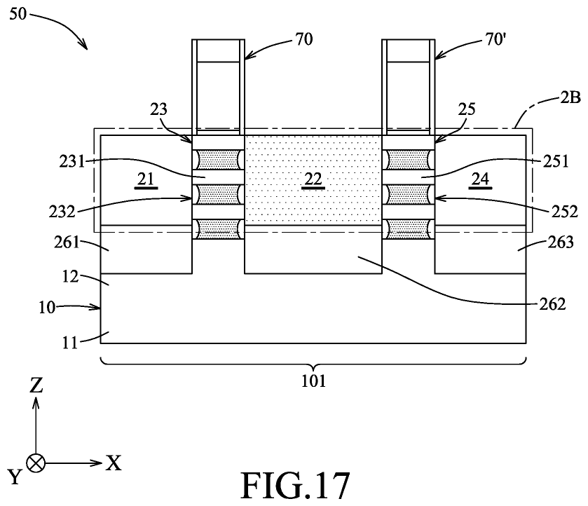

For example, FIGS. 16 and 17 illustrate schematic views of intermediate stages of the method 40 for manufacturing, for example, but not limited to, the diode-containing component 20B in the semiconductor structure 2 shown in FIG. 4 in accordance with some embodiments. In step S41, referring to the example illustrated in FIG. 16, the patterned structure 50 further includes the second stack 25 formed on the first part 101 and spaced apart from the first stack 23 in the X direction, and an additional preformed gate structure 70′ formed over the second stack 25 using a manner similar to that as described above with reference to FIGS. 6 to 11. Afterwards, in step S42, referring to the example illustrated in FIG. 16, the additional isolation portion 263 is formed on the first part 101 using a manner similar to that as described above with reference to FIG. 12, such that the isolation portions 262, 263 are located at the two opposite sides of the second stack 25, respectively. It is noted that the two end surfaces of each of the second semiconductor regions 251 in the second stack 25 are not covered by the two isolation portions 262, 263. Subsequently, in step S43, the third portion 24 is further formed on the additional isolation portion 263 using a manner similar to that as described above with reference to FIGS. 13 and 14, such that each of second semiconductor regions 251 and the second dielectric regions 252 in the second stack 25 extends between the second portion 22 and the third portion 24. In some embodiments, the first portion 21 and the third portion 24 may be simultaneously formed. After step S43, the structure shown in area 2B of FIG. 17 may function as the BJT as described above with reference to FIG. 4. Eventually, in step S44, the additional inter-layer dielectric portion 293 are formed to cover the third portion 24, the additional contact portion 283 are formed in the additional inter-layer dielectric portion 293 to be connected to the third portion 24, and the additional preformed gate structure 70′ is replaced with the second dummy gate structure 272 using any suitable processes. Accordingly, the structure shown in FIG. 17 is formed into the diode-containing component 20B in semiconductor structure 2 shown in FIG. 4.

In the semiconductor structure of this disclosure, with the introduction of the isolation portions in the diode-containing component, each of the terminals is entirely separated from the base structure and from an adjacent one of the terminals, thereby reducing occurrence of current leakage. Furthermore, with the introduction of the dielectric regions alternating with the semiconductor regions which interconnect the two portions having opposite conductivity types in the diode-containing component, the current flow between the two portions through the semiconductor regions may be enlarged. Additionally, the diode-containing component may be formed together with the active component using an integrated process flow. Therefore, the semiconductor structure and the methods for making the same of this disclosure may achieve an improved electrical performance of the diode-containing component, and enable implementation of various circuit design.

In accordance with some embodiments of the present disclosure, a semiconductor structure includes: a base structure; a first portion disposed on the base structure and made of a first semiconductor material; a second portion disposed on the base structure and spaced apart from the first portion, the second portion being made of a second semiconductor material which has a conductivity type opposite to that of the first semiconductor material; and a first stack disposed on the base structure and between the first portion and the second portion, the first stack including a plurality of first semiconductor regions spaced apart from each other, and a plurality of first dielectric regions disposed to alternate with the first semiconductor regions such that each of the first semiconductor regions and the first dielectric regions extends between the first portion and the second portion, the first semiconductor regions having a dopant concentration which is lower than that of each of the first portion and the second portion.

In accordance with some embodiments of the present disclosure, each of the first dielectric regions is disposed to fill a space between two corresponding adjacent ones of the first semiconductor regions.

In accordance with some embodiments of the present disclosure, each of the first dielectric regions includes a main part and two lateral parts which are respectively disposed at two opposite sides of the main part, and which are respectively connected to the first portion and the second portion.

In accordance with some embodiments of the present disclosure, the semiconductor structure further includes two isolation portions each of which is disposed between the base structure and a corresponding one of the first portion and the second portion, an upper surface of each of the isolation portions being at a level which is lower than a level of a lower surface of a bottommost one of the first semiconductor regions, and which is higher than a level of a lower surface of a bottommost one of the first dielectric regions.

In accordance with some embodiments of the present disclosure, the first portion and the second portion are spaced apart from each other in an X direction. The first semiconductor regions are spaced apart from each other in a Z direction transverse to the X direction. The semiconductor structure further includes a first dummy gate structure which is elongated in a Y direction transverse to both the X direction and the Z direction, and which is disposed over the first stack, and two contact portions which are connected to the first portion and the second portion, respectively.

In accordance with some embodiments of the present disclosure, the semiconductor structure further includes: a third portion disposed on the base structure such that the second portion is disposed between and spaced apart from the first portion and the third portion, the third portion being made of a third semiconductor material which has a conductivity type the same as that of the first semiconductor material; and a second stack disposed on the base structure and between the second portion and the third portion, the second stack including a plurality of second semiconductor regions spaced apart from each other, and a plurality of second dielectric regions disposed to alternate with the second semiconductor regions such that each of the second semiconductor regions and the second dielectric regions extends between the second portion and the third portion, the second semiconductor regions having a dopant concentration which is lower than that of each of the second portion and the third portion.

In accordance with some embodiments of the present disclosure, each of the second dielectric regions is disposed to fill a space between two corresponding adjacent ones of the second semiconductor regions.

In accordance with some embodiments of the present disclosure, each of the first dielectric regions and the second dielectric regions includes a main part and two lateral parts which are respectively disposed at two opposite sides of the main part. The two lateral parts of each of the first dielectric regions are connected to the first portion and the second portion, respectively. The two lateral parts of each of the second dielectric regions are connected to the second portion and the third portion, respectively.

In accordance with some embodiments of the present disclosure, the semiconductor structure further includes three isolation portions each of which is disposed between the base structure and a corresponding one of the first portion, the second portion and the third portion, and each of which is configured to entirely separate the corresponding one of the first portion, the second portion and the third portion from the base structure.

In accordance with some embodiments of the present disclosure, each of the first dielectric regions and the second dielectric regions includes silicon oxide, metal oxide, or a combination thereof.

In accordance with some embodiments of the present disclosure, a semiconductor structure includes: a base structure; a first portion disposed on the base structure and made of a first semiconductor material; a second portion disposed on the base structure and spaced apart from the first portion, the second portion being made of a second semiconductor material which has a conductivity type opposite to that of the first semiconductor material; a first stack disposed on the base structure and between the first portion and the second portion, the first stack including a plurality of first semiconductor regions spaced apart from each other such that each of the first semiconductor regions extends between the first portion and the second portion, the first semiconductor regions having a dopant concentration which is lower than that of each of the first portion and the second portion; and two isolation portions each of which is disposed between the base structure and a corresponding one of the first portion and the second portion, an upper surface of each of the isolation portions being at a level lower than a level of a lower surface of a bottommost one of the first semiconductor regions, and higher than a level of an upper surface of the base structure.

In accordance with some embodiments of the present disclosure, the first stack further includes a plurality of first dielectric regions disposed to alternate with the first semiconductor regions such that each of the first dielectric regions is disposed to fill a space between two corresponding adjacent ones of the first semiconductor regions and extends between the first portion and the second portion.

In accordance with some embodiments of the present disclosure, the semiconductor structure further includes: a third portion disposed on the base structure such that the second portion is disposed between and spaced apart from the first portion and the third portion, the third portion being made of a third semiconductor material which has a conductivity type the same as that of the first semiconductor material; a second stack disposed on the base structure and between the second portion and the third portion, the second stack including a plurality of second semiconductor regions spaced apart from each other, and a plurality of second dielectric regions disposed to alternate with the second semiconductor regions such that each of the second semiconductor regions and the second dielectric regions extends between the second portion and the third portion, the second semiconductor regions having a dopant concentration which is lower than that of each of the second portion and the third portion; and an additional isolation portion disposed between the base structure and the third portion, an upper surface of the additional isolation portion being at a level which is lower than a level of a lower surface of a bottommost one of the second semiconductor regions, and which is higher than a level of a lower surface of a bottommost one of the second dielectric regions.

In accordance with some embodiments of the present disclosure, each of the second dielectric regions is disposed to fill a space between two corresponding adjacent ones of the second semiconductor regions.

In accordance with some embodiments of the present disclosure, a method for manufacturing a semiconductor structure includes: forming a base structure; forming a first portion on the base structure, the first portion being made of a first semiconductor material; forming a second portion on the base structure and spaced apart from the first portion in an X direction, the second portion being made of a second semiconductor material which has a conductivity type opposite to that of the first semiconductor material; and forming a first stack on the base structure and between the first portion and the second portion, the first stack including a plurality of first semiconductor regions spaced apart from each other in a Z direction transverse to the X direction, and a plurality of first dielectric regions disposed to alternate with the first semiconductor regions in the Z direction such that each of the first semiconductor regions and the first dielectric regions extends between the first portion and the second portion, the first semiconductor regions having a dopant concentration which is lower than that of each of the first portion and the second portion.

In accordance with some embodiments of the present disclosure, the method further includes: forming a third portion on the base structure such that the second portion is disposed between and spaced apart from the first portion and the third portion in the X direction, the third portion being made of a third semiconductor material which has a conductivity type the same as that of the first semiconductor material; and forming a second stack on the base structure and between the second portion and the third portion, the second stack including a plurality of second semiconductor regions spaced apart from each other in the Z direction, and a plurality of second dielectric regions disposed to alternate with the second semiconductor regions in the Z direction such that each of the second semiconductor regions and the second dielectric regions extends between the second portion and the third portion, the second semiconductor regions having a dopant concentration which is lower than that of each of the second portion and the third portion.

In accordance with some embodiments of the present disclosure, the method further includes: forming three isolation portions, each of which is disposed between the base structure and a corresponding one of the first portion, the second portion and the third portion, and each of which is configured to entirely separate the corresponding one of the first portion, the second portion and the third portion from the base structure.

In accordance with some embodiments of the present disclosure, the method further includes forming two dummy gate structures over the first stack and the second stack, respectively, the two dummy gate structures being each elongated in a Y direction transverse to both the X direction and the Z direction.

In accordance with some embodiments of the present disclosure, formation of the first stack includes: forming a preformed stack including the first semiconductor regions and a plurality of preformed semiconductor regions disposed to alternate with the first semiconductor regions in the Z direction, the preformed semiconductor regions being made of a material different from that of the first semiconductor regions; and replacing the preformed semiconductor regions with the first dielectric regions, respectively.

In accordance with some embodiments of the present disclosure, each of the first dielectric regions includes a main part and two lateral parts which are respectively disposed at two opposite sides of the main part in the X direction, and which are connected to the first portion and the second portion, respectively. The first stack is formed before forming the first portion and before forming the second portion. Formation of the first stack includes: forming a preformed stack including the first semiconductor regions and a plurality of preformed semiconductor regions disposed to alternate with the first semiconductor regions in the Z direction, the preformed semiconductor regions being made of a material different from that of the first semiconductor regions; replacing the preformed semiconductor regions with a plurality of first dielectric layers, respectively; recessing the first dielectric layers such that the first dielectric layers are each recessed to form two lateral grooves and such that each of the recessed first dielectric layers serves as the main part of a corresponding one of the first dielectric regions; and forming the two lateral parts of each of the first dielectric regions respectively in the two lateral grooves of a corresponding one of the recessed first dielectric layers.

In accordance with some embodiments of the present disclosure, a semiconductor structure includes: a base structure having a first part and a second part displaced from the first part; a diode-containing component disposed on the first part and including a first portion disposed on the first part and made of a first semiconductor material, a second portion disposed on the first part and spaced apart from the first portion, the second portion being made of a second semiconductor material which has a conductivity type opposite to that of the first semiconductor material, and a first stack disposed on the first part and between the first portion and the second portion, the first stack including a plurality of first semiconductor regions spaced apart from each other, and a plurality of first dielectric regions disposed to alternate with the first semiconductor regions such that each of the first semiconductor regions and the first dielectric regions extends between the first portion and the second portion, the first semiconductor regions having a dopant concentration which is lower than that of each of the first portion and the second portion; and an active component disposed on the second part, the active component including a channel portion and an active gate structure, the active gate structure including a gate electrode which is isolated from the channel portion and which is used to control an electrical conductivity of the channel portion.

In accordance with some embodiments of the present disclosure, the first portion and the second portion are spaced apart from each other in an X direction. The first semiconductor regions are spaced apart from each other in a Z direction transverse to the X direction. The diode-containing component further includes a first dummy gate structure which is elongated in a Y direction transverse to both the X direction and the Z direction, and which is disposed over the first stack.

In accordance with some embodiments of the present disclosure, the active component further includes two source/drain portions having a conductivity type which is the same as that of one of the first portion and the second portion, the two source/drain portions being spaced apart from each other in the X direction. The channel portion is disposed between the two source/drain portions and made of a semiconductor material the same as that of the first semiconductor regions. The active gate structure is elongated in the Y direction, and is disposed over the channel portion, the active gate structure being made of a material the same as that of the first dummy gate structure.

In accordance with some embodiments of the present disclosure, the diode-containing component functions as a PIN diode. One of the first portion and the second portion has a p-type conductivity and serves as an anode of the PIN diode, and the other one of the first portion and the second portion has an n-type conductivity and serves as a cathode of the PIN diode.

In accordance with some embodiments of the present disclosure, the diode-containing component further includes: a third portion disposed on the base structure such that the second portion is disposed between and spaced apart from the first portion and the third portion, the third portion being made of a third semiconductor material which has a conductivity type the same as that of the first semiconductor material; and a second stack disposed on the base structure and between the second portion and the third portion, the second stack including a plurality of second semiconductor regions spaced apart from each other, and a plurality of second dielectric regions disposed to alternate with the second semiconductor regions such that each of the second semiconductor regions and the second dielectric regions extends between the second portion and the third portion, the second semiconductor regions having a dopant concentration which is lower than that of each of the second portion and the third portion. The diode-containing component functions as a bipolar junction transistor, the first portion, the second portion and the third portion respectively serving as a collector terminal, a base terminal and an emitter terminal of the bipolar junction transistor.

In accordance with some embodiments of the present disclosure, the diode-containing component further includes three isolation portions each of which is disposed between the base structure and a corresponding one of the first portion, the second portion and the third portion, and each of which is configured to entirely separate the corresponding one of the first portion, the second portion and the third portion from the base structure.

The foregoing outlines features of several embodiments so that those skilled in the art may better understand the aspects of the present disclosure. Those skilled in the art should appreciate that they may readily use the present disclosure as a basis for designing or modifying other processes or structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor structure, comprising:
a base structure;
a first portion disposed on the base structure and made of a first semiconductor material;
a second portion disposed on the base structure and spaced apart from the first portion, the second portion being made of a second semiconductor material which has a conductivity type opposite to that of the first semiconductor material; and
a first stack disposed on the base structure and between the first portion and the second portion, the first stack including a plurality of first semiconductor regions spaced apart from each other, and a plurality of first dielectric regions disposed to alternate with the first semiconductor regions such that each of the first semiconductor regions and the first dielectric regions extends between the first portion and the second portion, the first semiconductor regions having a dopant concentration which is lower than that of each of the first portion and the second portion.

2. The semiconductor structure as claimed in claim 1, wherein each of the first dielectric regions is disposed to fill a space between two corresponding adjacent ones of the first semiconductor regions.

3. The semiconductor structure as claimed in claim 1, wherein each of the first dielectric regions includes a main part and two lateral parts which are respectively disposed at two opposite sides of the main part, and which are respectively connected to the first portion and the second portion.

4. The semiconductor structure as claimed in claim 1, further comprising two isolation portions each of which is disposed between the base structure and a corresponding one of the first portion and the second portion, an upper surface of each of the isolation portions being at a level which is lower than a level of a lower surface of a bottommost one of the first semiconductor regions, and which is higher than a level of a lower surface of a bottommost one of the first dielectric regions.

5. The semiconductor structure as claimed in claim 1, wherein:
the first portion and the second portion are spaced apart from each other in an X direction;
the first semiconductor regions are spaced apart from each other in a Z direction transverse to the X direction; and
the semiconductor structure further comprises
a first dummy gate structure which is elongated in a Y direction transverse to both the X direction and the Z direction, and which is disposed over the first stack, and
two contact portions which are connected to the first portion and the second portion, respectively.

6. The semiconductor structure as claimed in claim 1, further comprising:
a third portion disposed on the base structure such that the second portion is disposed between and spaced apart from the first portion and the third portion, the third portion being made of a third semiconductor material which has a conductivity type the same as that of the first semiconductor material; and
a second stack disposed on the base structure and between the second portion and the third portion, the second stack including a plurality of second semiconductor regions spaced apart from each other, and a plurality of second dielectric regions disposed to alternate with the second semiconductor regions such that each of the second semiconductor regions and the second dielectric regions extends between the second portion and the third portion, the second semiconductor regions having a dopant concentration which is lower than that of each of the second portion and the third portion.

7. The semiconductor structure as claimed in claim 6, wherein each of the second dielectric regions is disposed to fill a space between two corresponding adjacent ones of the second semiconductor regions.

8. The semiconductor structure as claimed in claim 6, wherein:
each of the first dielectric regions and the second dielectric regions includes a main part and two lateral parts which are respectively disposed at two opposite sides of the main part;
the two lateral parts of each of the first dielectric regions are connected to the first portion and the second portion, respectively; and
the two lateral parts of each of the second dielectric regions are connected to the second portion and the third portion, respectively.

9. The semiconductor structure as claimed in claim 6, further comprising:
three isolation portions each of which is disposed between the base structure and a corresponding one of the first portion, the second portion and the third portion, and each of which is configured to entirely separate the corresponding one of the first portion, the second portion and the third portion from the base structure.

10. The semiconductor structure as claimed in claim 6, wherein each of the first dielectric regions and the second dielectric regions includes silicon oxide, metal oxide, or a combination thereof.

11. A semiconductor structure comprising:
a base structure;
a first portion disposed on the base structure and made of a first semiconductor material;
a second portion disposed on the base structure and spaced apart from the first portion, the second portion being made of a second semiconductor material which has a conductivity type opposite to that of the first semiconductor material;
a first stack disposed on the base structure and between the first portion and the second portion, the first stack including a plurality of first semiconductor regions spaced apart from each other such that each of the first semiconductor regions extends between the first portion and the second portion, the first semiconductor regions having a dopant concentration which is lower than that of each of the first portion and the second portion;
and two isolation portions each of which is disposed between the base structure and a corresponding one of the first portion and the second portion, an upper surface of each of the isolation portions being at a level lower than a level of a lower surface of a bottommost one of the first semiconductor regions, and higher than a level of an upper surface of the base structure.

12. The semiconductor structure as claimed in claim 11, wherein the first stack further includes a plurality of first dielectric regions disposed to alternate with the first semiconductor regions such that each of the first dielectric regions is disposed to fill a space between two corresponding adjacent ones of the first semiconductor regions and extends between the first portion and the second portion.

13. The semiconductor structure as claimed in claim 12, further comprising:
a third portion disposed on the base structure such that the second portion is disposed between and spaced apart from the first portion and the third portion, the third portion being made of a third semiconductor material which has a conductivity type the same as that of the first semiconductor material;
a second stack disposed on the base structure and between the second portion and the third portion, the second stack including a plurality of second semiconductor regions spaced apart from each other, and a plurality of second dielectric regions disposed to alternate with the second semiconductor regions such that each of the second semiconductor regions and the second dielectric regions extends between the second portion and the third portion, the second semiconductor regions having a dopant concentration which is lower than that of each of the second portion and the third portion; and
an additional isolation portion disposed between the base structure and the third portion, an upper surface of the additional isolation portion being at a level which is lower than a level of a lower surface of a bottommost one of the second semiconductor regions, and which is higher than a level of a lower surface of a bottommost one of the second dielectric regions.

14. The semiconductor structure as claimed in claim 13, wherein each of the second dielectric regions is disposed to fill a space between two corresponding adjacent ones of the second semiconductor regions.

15. A method for manufacturing a semiconductor structure, comprising:
forming a base structure;
forming a first portion on the base structure, the first portion being made of a first semiconductor material;
forming a second portion on the base structure and spaced apart from the first portion in an X direction, the second portion being made of a second semiconductor material which has a conductivity type opposite to that of the first semiconductor material; and
forming a first stack on the base structure and between the first portion and the second portion, the first stack including a plurality of first semiconductor regions spaced apart from each other in a Z direction transverse to the X direction, and a plurality of first dielectric regions disposed to alternate with the first semiconductor regions in the Z direction such that each of the first semiconductor regions and the first dielectric regions extends between the first portion and the second portion, the first semiconductor regions having a dopant concentration which is lower than that of each of the first portion and the second portion.

16. The method as claimed in claim 15, further comprising:
forming a third portion on the base structure such that the second portion is disposed between and spaced apart from the first portion and the third portion in the X direction, the third portion being made of a third semiconductor material which has a conductivity type the same as that of the first semiconductor material; and
forming a second stack on the base structure and between the second portion and the third portion, the second stack including a plurality of second semiconductor regions spaced apart from each other in the Z direction, and a plurality of second dielectric regions disposed to alternate with the second semiconductor regions in the Z direction such that each of the second semiconductor regions and the second dielectric regions extends between the second portion and the third portion, the second semiconductor regions having a dopant concentration which is lower than that of each of the second portion and the third portion.

17. The method as claimed in claim 16, further comprising forming three isolation portions, each of which is disposed between the base structure and a corresponding one of the first portion, the second portion and the third portion, and each of which is configured to entirely separate the corresponding one of the first portion, the second portion and the third portion from the base structure.

18. The method as claimed in claim 16, further comprising forming two dummy gate structures over the first stack and the second stack, respectively, the two dummy gate structures being each elongated in a Y direction transverse to both the X direction and the Z direction.

19. The method as claimed in claim 15, wherein formation of the first stack includes
forming a preformed stack including the first semiconductor regions and a plurality of preformed semiconductor regions disposed to alternate with the first semiconductor regions in the Z direction, the preformed semiconductor regions being made of a material different from that of the first semiconductor regions, and
replacing the preformed semiconductor regions with the first dielectric regions, respectively.

20. The method as claimed in claim 15, wherein:
each of the first dielectric regions includes a main part and two lateral parts which are respectively disposed at two opposite sides of the main part in the X direction, and which are connected to the first portion and the second portion, respectively;
the first stack is formed before forming the first portion and before forming the second portion; and
formation of the first stack includes
forming a preformed stack including the first semiconductor regions and a plurality of preformed semiconductor regions disposed to alternate with the first semiconductor regions in the Z direction, the preformed semiconductor regions being made of a material different from that of the first semiconductor regions,
replacing the preformed semiconductor regions with a plurality of first dielectric layers, respectively,
recessing the first dielectric layers such that the first dielectric layers are each recessed to form two lateral grooves and such that each of the recessed first dielectric layers serves as the main part of a corresponding one of the first dielectric regions, and
forming the two lateral parts of each of the first dielectric regions respectively in the two lateral grooves of a corresponding one of the recessed first dielectric layers.
